(19) United States
(12) Patent Application Publication
(10) Pub. No.: US 2007/0114545 A1
(43) Pub. Date: May 24, 2007

(54) Vertical gallium-nitride based light emitting diode

(75) Inventors: Tae Sung Jang, Suwon (KR); Su Yeol Lee, Seongnam (KR)

Correspondence Address: MCDERMOTT WILL & EMERY LLP, 600 13TH STREET, N.W., WASHINGTON, DC, 20005-3096, US

(73) Assignee: SAMSUNG Electro-Mechanics Co., Ltd.

(21) Appl. No.: 11/602,311

(22) Filed: Nov. 21, 2006

(30) Foreign Application Priority Data
Nov. 23, 2005 (KR) 10-2005-0112163

(51) Int. Cl. H01L 33/00

(52) U.S. Cl. 257/94

(57) ABSTRACT

A vertical GaN-based LED includes: an n-type bonding pad; an n-electrode formed under the n-type bonding pad; an n-type transparent electrode formed under the n-electrode; an n-type GaN layer formed under the n-type transparent electrode; an active layer formed under the n-type GaN layer; a p-type GaN layer formed under the active layer; a current blocking layer formed under a predetermined portion of the p-type GaN layer corresponding to a region where the n-electrode is formed, the current blocking layer being formed of distributed Bragg reflector (DBR); a p-electrode formed under the resulting structure where the current blocking layer is formed; and a support layer formed under the p-electrode.

### CROSS-REFERENCE TO RELATED APPLICATIONS

This application claims the benefit of Korean Patent Application No. 2005-112163 filed with the Korean Industrial Property Office on Nov. 23, 2005, the disclosure of which is incorporated herein by reference.

### BACKGROUND OF THE INVENTION

1. Field of the Invention

The present invention relates to a vertical gallium-nitride (GaN)-based light emitting diode (LED), and more particularly, to a vertical GaN-based LED which can reflect photons emitted to a current blocking layer toward a light emitting layer, thereby implementing high brightness.

2. Description of the Related Art

Generally, GaN-based LEDs are grown on a sapphire substrate. The sapphire substrate is rigid and electrically nonconductive and has a low thermal conductivity. Therefore, it is difficult to reduce the size of the GaN-based LED for cost-down or improve the optical power and chip characteristics. Particularly, heat dissipation is very important for the LEDs because a large current should be applied to the GaN-based LEDs so as to increase the optical power of the GaN-based LEDs. To solve these problems, a vertical GaN-based LED has been proposed. In the vertical GaN-based LED, the sapphire substrate is removed using a laser lift-off (hereinafter, referred to as LLO) technology.

A conventional vertical GaN-based LED will be described below with reference to FIGS. 1 and 2.

FIG. 1 is a sectional view of a conventional vertical GaN-based LED. Referring to FIG. 1, the conventional vertical GaN-based LED includes an n-type bonding pad 110, an negative (n-) electrode 120 formed under the n-type bonding pad 110, an n-type transparent electrode 130 formed under the n-electrode 120 to improve the current spreading efficiency, an n-type GaN layer 140 formed under the n-type transparent electrode 130, an active layer 150 formed under the n-type GaN layer 140, a p-type GaN layer 160 formed under the active layer 150, a positive (p-) electrode 170 formed under the p-type GaN layer 160, and a support layer 190 formed under the p-electrode 170.

A reference numeral 180 represents a plating seed layer acting as a plating crystal nucleus when the support layer 190 is formed using electrolyte plating or electroless plating.

In such a conventional vertical GaN-based LED, one pair of electrodes, that is, the n-electrode 120 and the p-electrode 170, are arranged vertically to each other, with a light-emitting structure interposed therebetween. Specifically, the n-electrode 120 is arranged at the center portion of the upper surface of the light-emitting structure so as to improve the current spreading efficiency. Due to this structure, the current is concentrated on the light-emitting structure corresponding to the center portion between the n-electrode 120 and the p-electrode 170.

When the current is concentrated on the center portion of the light-emitting structure, light generated from the light-emitting structure is concentrated thereon. Consequently, the entire luminous efficiency of the LED is reduced, thus lowering the brightness of the LED.

To solve these problems, another conventional vertical GaN-based LED has been proposed as illustrated in FIG. 2. The conventional vertical GaN-based LED of FIG. 2 further includes a current blocking layer formed of insulating material, such as metal having high resistance or oxide, so as to prevent the current from flowing between the n-electrode 120 and the p-electrode 170.

As the conventional vertical GaN-based LED of FIG. 2 is provided with the current blocking layer, the current concentrated on the center portion between the n-electrode 120 and the p-electrode 170 is diffused to other regions. Therefore, the current spreading efficiency increases, resulting in the uniform light emission. However, because the current blocking layer is formed of the insulating material, such as metal having high resistance or oxide, some of light emitted from the light-emitting structure is absorbed or scattered. Consequently, the conventional vertical GaN-based LED has the problem in that the brightness of the LED is low.

### SUMMARY OF THE INVENTION

An advantage of the present invention is that it provides a vertical GaN-based LED that can improve the current spreading efficiency and implement high brightness. In the vertical GaN-based LED, a current blocking layer is formed of a distributed Bragg reflector (DBR) having high reflectivity, and photons emitted to the current blocking layer are reflected to an emission surface.

Additional aspects and advantages of the present general inventive concept will be set forth in part in the description which follows and, in part, will be obvious from the description, or may be learned by practice of the general inventive concept.

According to an aspect of the invention, a vertical GaN-based LED includes: an n-type bonding pad; an n-electrode formed under the n-type bonding pad; an n-type transparent electrode formed under the n-electrode; an n-type GaN layer formed under the n-type transparent electrode; an active layer formed under the n-type GaN layer; a p-type GaN layer formed under the active layer; a current blocking layer formed under a predetermined portion of the p-type GaN layer corresponding to a region where the n-electrode is formed, the current blocking layer being formed of a distributed Bragg reflector (DBR); a p-electrode formed under the resulting structure where the current blocking layer is formed; and a support layer formed under the p-electrode.

According to another aspect of the present invention, the n-electrode is formed of metal having high reflectivity. Therefore, the n-electrode can serve as an electrode and a reflective layer.

According to a further aspect of the present invention, the DBR includes at least one semiconductor pattern in which a low refractive-index layer and a high refractive-index layer are formed in sequence. The thicknesses of the low refractive-index layer and the high refractive-index layer are λ/4 of a reference wavelength.

The number of the semiconductor patterns for the DBR can be determined according to the wavelength of light to be emitted from the LED. The reflectivity of the current blocking layer formed of the DBR can be maximized.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view illustrating a conventional vertical GaN-based LED;

FIG. 2 is a sectional view illustrating another conventional vertical GaN-based LED;

FIG. 3 is a sectional view of a vertical GaN-based LED according to an embodiment of the present invention;

FIG. 4 is a partial sectional view of a current blocking layer according to an embodiment of the present invention;

FIG. 5 is a graph illustrating the variation of reflectivity in accordance with a thickness change in the current blocking layer of FIG. 4; and

FIG. 6 is a graph illustrating the variation of reflectivity in accordance with a reference wavelength in the current blocking layer of FIG. 4.

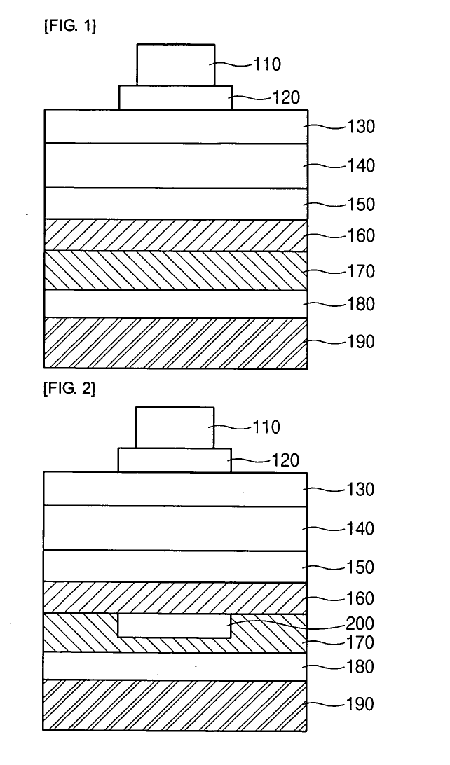

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

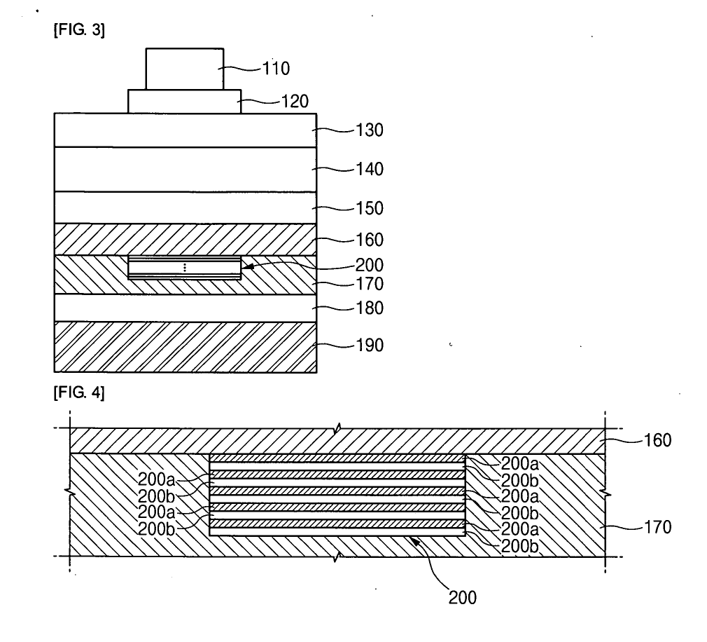

Hereinafter, a vertical GaN-based LED according to the embodiments of the present invention will be described in detail with reference to FIGS. 3 and 4.

FIG. 3 is a sectional view of a vertical GaN-based LED according to an embodiment of the present invention, and FIG. 4 is a partial sectional view of a current blocking layer illustrated in FIG. 3.

Referring to FIGS. 3 and 4, an n-type bonding pad 110 for electrical connection to an external device is formed on the uppermost portion of the vertical GaN-based LED.

An n-electrode 120 for improving the luminous efficiency is formed under the n-type bonding pad 110. It is preferable that the n-electrode 120 is formed of metal having high reflectivity so that it can serve as an electrode and a reflective layer.

An n-type GaN layer 140 is formed under the n-electrode 120. More specifically, the n-type GaN layer 140 may be formed of an n-doped GaN layer or an n-doped GaN/AlGaN layer.

To improve the current spreading efficiency, an n-type transparent electrode 130 is further formed on the n-type GaN layer 140.

An active layer 150 and a p-type GaN layer 160 are sequentially formed under the n-type GaN layer 140, thereby forming a GaN-based LED structure.

The active layer 140 of the GaN-based LED structure may have a multi-quantum well structure of InGaN/GaN layer. Like the n-type GaN layer 140, the p-type GaN layer 160 may be formed of a p-doped GaN layer or a p-doped GaN/AlGaN layer.

A current blocking layer 200 is formed under a predetermined portion of the p-type GaN layer 160 corresponding to a region where the n-electrode 120 is formed. The current blocking layer 200 minimizes the concentration of the current on the center portion of the GaN-based LED structure.

Specifically, the current blocking layer 200 is formed of a distributed Bragg reflector (DBR). The DBR is a reflector that is formed of semiconductor patterns and can obtain the reflectivity of more than 95% in the light of specific wavelength (λ) by alternately forming two mediums having different refractive index to the thickness of λ/4n (λ: wavelength of light, n: refractive index of medium, m: odd number). Because the DBR has higher bandgap energy than the oscillation wavelength, the absorption does not occur. As the difference in refractive index between the two mediums composing the semiconductor patterns becomes greater, the reflectivity increases.

Accordingly, as illustrated in FIG. 4, the current blocking layer 200 formed of the DBR includes at least one semiconductor pattern in which a low refractive-index layer 200a and a high refractive-index layer 200b are alternately formed. At this point, the thicknesses of the low refractive-index layer and the high refractive-index layer are λ/4 of the reference wavelength.

More specifically, the low refractive-index layer 200a composing the current blocking layer 200 has a relatively lower reflective index than the high refractive-index layer 200b. For example, the low refractive-index layer 200a is formed of SiO₂ (n=1.4) or Al₂O₃ (n=1.6), and the high refractive-index layer 200b is formed of Si₃N₄ (n=2.05-2.25), TiO₂ (n=2.1), or Si—H (n=3.2).

In this embodiment, the low refractive-index layer 200a is formed of Al₂O₃ (n=1.6), and the high refractive-index layer 200b is formed of Si₃N₄ (n=2.05-2.25).

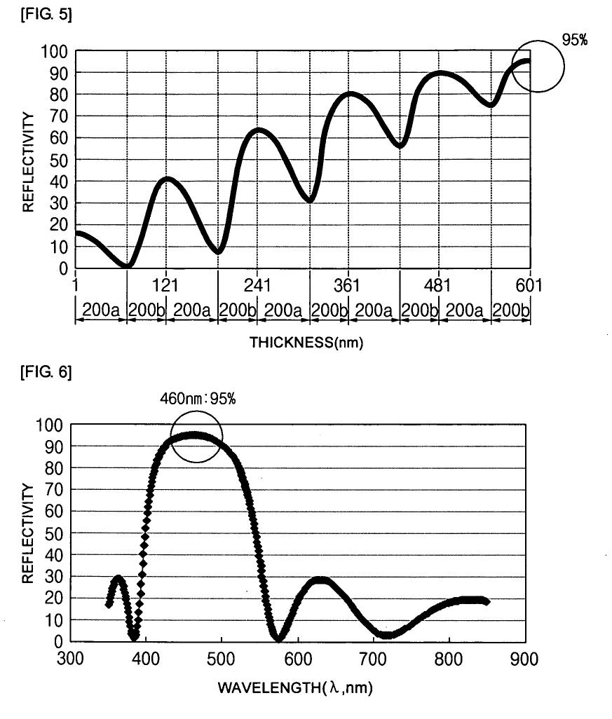

Meanwhile, the number of the semiconductor patterns in which the low refractive-index layer 200a and the high refractive-index layer 200b are formed in sequence can be adjusted according to the wavelength of light to be emitted from the LED. As illustrated in FIGS. 5 and 6, the present invention can maximize the reflectivity of the current blocking layer formed of the DBR.

FIG. 5 is a graph illustrating the variation of reflectivity in accordance with the thickness change in the current blocking layer of FIG. 4, and FIG. 6 is a graph illustrating the variation of reflectivity according to the reference wavelength in the current blocking layer of FIG. 4.

The current blocking layer had the reference wavelength of 460 nm, and the thickness of the current blocking layer was changed in accordance with the reference wavelength.

A p-electrode 170 is formed under the p-type GaN layer 160 where the current blocking layer 200 is formed. Like the n-electrode 120, it is preferable that the p-electrode 170 is formed of metal having high reflectivity so that it can serve as an electrode and a reflective layer.

A support layer 190 is formed under the p-electrode 170. The support layer 190 includes a plating layer that is formed using a plating crystal nucleus layer 180 by electrolyte plating or electroless plating.

Although the support layer 190 is provided with the plating layer formed by using the plating crystal nucleus layer 180 as a crystal nucleus, the present invention is not limited to the plating layer. That is, the support layer may be formed of a Si substrate, a GaAs substrate, a Ge substrate, or a metal layer, which can serve as a support layer of a final LED and an electrode.

In addition, the metal layer may be formed using thermal evaporator, e-beam evaporator, sputter, and chemical vapor deposition (CVD).

As described above, the current blocking layer is formed of DBR having high reflectivity. Therefore, the current spreading efficiency can be improved, and the phenomenon that the light emitted toward the current blocking layer is absorbed or scattered into the current blocking layer can be minimized. Consequently, the optical extraction efficiency is improved and thus the improvement of the external quantum efficiency is maximized.

Therefore, the present invention can provide the vertical GaN-based LED having high brightness.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A vertical gallium-nitride (GaN)-based light emitting diode (LED) comprising:
an n-type bonding pad;
an n-electrode formed under the n-type bonding pad;
an n-type transparent electrode formed under the n-electrode;
an n-type GaN layer formed under the n-type transparent electrode;
an active layer formed under the n-type GaN layer;
a p-type GaN layer formed under the active layer;
a current blocking layer formed under a predetermined portion of the p-type GaN layer corresponding to a region where the n-electrode is formed, the current blocking layer being formed of distributed Bragg reflector (DBR);
a p-electrode formed under the resulting structure where the current blocking layer is formed; and
a support layer formed under the p-electrode.

2. The vertical GaN-based LED according to claim 1,
wherein the n-electrode is formed of metal having high reflectivity.

3. The vertical GaN-based LED according to claim 1,
wherein the DBR includes at least one semiconductor pattern in which a low refractive-index layer and a high refractive-index layer are formed in sequence.

4. The vertical GaN-based LED according to claim 3,
wherein the low refractive-index layer has a relatively lower refractive index than that of the high refractive-index layer.

5. The vertical GaN-based LED according to claim 3,
wherein the thicknesses of the low refractive-index layer and the high refractive-index layer are λ/4 of a reference wavelength.
